(19) United States
(12) Patent Application Publication
(10) Pub. No.: US 2026/0105951 A1
(43) Pub. Date: Apr. 16, 2026

(54) MEMORY DEVICE WITH DATA RETENTION CHARACTERISTICS AND OPERATING METHOD THEREOF

(71) Applicant: SAMSUNG ELECTRONICS CO., LTD., Suwon-si (KR)

(72) Inventors: Myungkyu LEE, Suwon-si (KR); Yejun Ko, Suwon-si (KR); Jinwoo Seong, Suwon-si (KR); Kyomin Sohn, Suwon-si (KR); Kijun Lee, Suwon-si (KR); Eunae Lee, Suwon-si (KR); Sunghye Cho, Suwon-si (KR)

(73) Assignee: SAMSUNG ELECTRONICS CO., LTD., Suwon-si (KR)

(21) Appl. No.: 19/200,104

(22) Filed: May 6, 2025

(30) Foreign Application Priority Data
Oct. 14, 2024 (KR) 10-2024-0139727

(51) Int. Cl. G11C 11/4091

(52) U.S. Cl. CPC G11C 11/4091; G11C 2211/4062

(57) ABSTRACT

A memory device includes a memory cell array including a plurality of word lines, a sense amplifier circuit, and a control logic circuit. The sense amplifier circuit is configured to amplify read data obtained from active memory cells of an active word line from among the plurality of word lines, and provide write data from a memory controller to the active memory cells. The control logic circuit is configured to store, based on activation of a first word line of the plurality of word lines, inverted first data in memory cells of the first word line by inverting first data of the memory cells of the first word line stored in the sense amplifier circuit.

### CROSS-REFERENCE TO RELATED APPLICATIONS

This application claims benefit of priority under 35 U.S.C. § 119 to Korean Patent Application No. 10-2024-0139727, filed on Oct. 14, 2024, in the Korean Intellectual Property Office, the disclosure of which is incorporated by reference herein in its entirety.

### BACKGROUND

### 1. Field

The present disclosure relates generally to memory devices, and more particularly, to a memory device with data retention characteristics and an operating method thereof.

### 2. Description of Related Art

Recently, an integration degree and/or a speed of memory devices used in relatively high-performance electronic systems may have increased. However, data retention characteristics of memory devices such as, but not limited to, dynamic random access memory (DRAM), or the like, may be degraded due to charge loss. For example, when access frequency of memory cells in particular positions increases, data retention characteristics of adjacent memory cells may be significantly degraded. As another example, when a particular word line is frequently active, data retention characteristics of memory cells connected to a weak word line, which may be adjacent to the particular word line, may be deteriorated. Attempts to secure data reliability of the memory cells connected to the weak word line may include performing a target refresh with respect to the weak word line.

When an integration degree of a memory device increases, data retention characteristics of the memory device may also be further deteriorated. In addition, as the number of word lines to be refreshed increases, there may be a limit in increasing the frequency of performing target refresh on the weak word lines within a refresh cycle. That is, despite performing various operations to attempt to address data reliability, there is a need for further improvements to the data retention characteristics of memory cells to secure data reliability.

### SUMMARY

One or more example embodiments of the present disclosure provide a memory device in which data retention characteristics and data reliability are improved, when compared to related memory devices, by reducing an amount of disturb occurring between memory cells, and an operating method of the memory device.

According to an aspect of the present disclosure, a memory device includes a memory cell array including a plurality of word lines, a sense amplifier circuit, and a control logic circuit. The sense amplifier circuit is configured to amplify read data obtained from active memory cells of an active word line from among the plurality of word lines, and provide write data from a memory controller to the active memory cells. The control logic circuit is configured to store, based on activation of a first word line of the plurality of word lines, inverted first data in memory cells of the first word line by inverting first data of the memory cells of the first word line stored in the sense amplifier circuit.

According to an aspect of the present disclosure, an operating method of a memory device includes activating a first word line from among a plurality of word lines of the memory device, based on reception of an active command from a memory controller, storing, in a sense amplifier circuit, first data read from first memory cells of the first word line, storing, based on reception of a first command from the memory controller, inverted first data in the first memory cells by inverting the first data stored in the sense amplifier circuit, and storing, in a storage circuit of the memory device, a first flag indicating a polarity of the first data stored in the first memory cells.

According to an aspect of the present disclosure, an operating method of a memory device includes activating a word line from among a plurality of word lines of the memory device based on reception of an active command from a memory controller, storing, in memory cells of the word line based on the word line being active, inverted data obtained by inverting data of the memory cells of the word line stored in a sense amplifier circuit of the memory device, updating, in a first per-row activation counting (PRAC) cell of the memory device corresponding to the word line, an activation count of the word line, and updating, in a second PRAC cell of the memory device, a flag indicating a polarity of data stored in the memory cells of the word line to a predetermined value, based on the polarity of the data stored in the memory cells of the word line being inverted.

Additional aspects may be set forth in part in the description that follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram of a memory system, according to an embodiment;

FIG. 2 is a diagram illustrating an example of a disturb amount according to data patterns of an aggressor word line and a weak word line, according to an embodiment;

FIG. 3 is a flowchart illustrating an operating method of a memory device, according to an embodiment;

FIGS. 4A and 4B illustrate an operating method of a memory device, according to an embodiment;

FIG. 5 is a block diagram illustrating an example of a memory device, according to an embodiment;

FIG. 6 is a diagram illustrating an accumulated disturb amount depending on application of inversion processing, according to an embodiment;

FIGS. 7, 8A, and 8B are each a diagram illustrating an example of inversion processing of data values in various memory operations, according to an embodiment;

FIG. 9 is a circuit diagram illustrating an example of a bit line sense amplifier, according to some embodiments;

FIGS. 10A and 10B are each a diagram illustrating an example in which polarity information is stored, according to some embodiments;

FIG. 11 is a flowchart illustrating a specific example of an operating method of a memory device, according to an embodiment;

FIG. 12 is a flowchart illustrating an operating method of a memory device, according to an embodiment;

FIG. 13 is a block diagram of a memory system, according to an embodiment; and

FIG. 14 is a block diagram illustrating a data center including a system, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). For example, the terms “first”, “second”, “third”, or the like may not necessarily involve an order or a numerical meaning of any form.

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element. It is to be understood that when an element or layer is referred to as being “connected to” or “coupled to” another element or layer, it may be directly connected or coupled to the other element or layer or intervening elements or layers may be present. In contrast, when an element is referred to as being “directly connected to” or “directly coupled to” another element or layer, there are no intervening elements or layers present.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as, but not limited to, device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

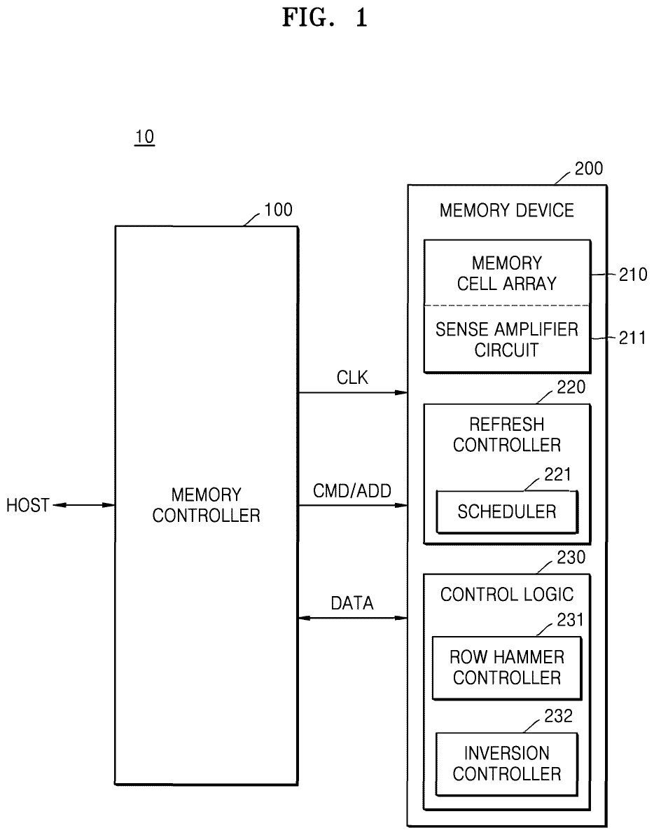

FIG. 1 is a block diagram of a memory system, according to an example embodiment.

Referring to FIG. 1, a memory system 10 may include a memory controller 100 and a memory device 200. The memory device 200 may include a memory cell array 210, a sense amplifier circuit 211, a refresh controller 220, and a control logic 230. In addition, in an embodiment, the control logic 230 may include a row hammer controller 231 and an inversion controller 232. The control logic 230 may refer to various components in the memory device 200, and at least one of the row hammer controller 231 and the inversion controller 232 may be provided outside of the control logic 230. The control logic 230 may refer to at least one circuit configured to perform various functions relating to memory operations and may include related components. For example, the control logic 230 may control internal operations of the memory device 200 based on decoding results of command/address CMD/ADD. In an embodiment, the control logic 230 may be physically implemented by analog and/or digital circuits including one or more of a logic gate, an integrated circuit, a microprocessor, a microcontroller, a memory circuit, a passive electronic component, an active electronic component, an optical component, or the like. For example, a field programmable gate array (FPGA) may be used to implement custom logic that may include the functionality of the control logic 230. As another example, a processor in combination with a memory may be used to execute one or more instructions to perform the functionality of the control logic 230. Alternatively or additionally, at least a portion of the functionality of control logic 230 may be incorporated into the memory controller 100 and/or implemented as instructions to be executed by the memory controller 100.

The memory controller 100 may control memory operations such as, but not limited to, writing, reading, or the like by providing various signals to the memory device 200 through an interface circuit. For example, the memory controller 100 may access data DATA of the memory cell array 210 by providing a clock signal CLK and the command/address CMD/ADD to the memory device 200. The command CMD may include a command for a normal memory operation such as, but not limited to, data writing, data reading, or the like. In addition, when the memory device 200 includes a dynamic random access memory (DRAM) cell, the command CMD may include a refresh command for refreshing various operations relating to the DRAM (e.g., memory cells).

The memory controller 100 may communicate with a host HOST by using various programs and may access the memory device 200 upon a request from the host HOST. Although FIG. 1 illustrates that the host is a device provided outside of the memory controller 100, the host may include the memory controller 100. When explaining embodiments below, the memory controller 100 may be described as accessing the memory device 200. However, in some embodiments, the host including the memory controller 100 may access the memory device 200.

The memory cell array 210 may include a plurality of word lines, and each word line may be connected to a plurality of memory cells. For example, memory cells connected to one word line may be referred to as a row. That is, the memory cell array 210 may include a plurality of rows. The sense amplifier circuit 211 may be connected to the memory cell array 210 through a plurality of bit lines and may include a sense amplifier corresponding to each bit line. The sense amplifier circuit 211 may store and/or amplify data read from the memory cell array 210, and during a write operation, read data may be provided to the memory cell array 210 through the sense amplifier circuit 211. In embodiments, when the refresh is performed with respect to a word line, it may indicate that memory cells connected to one word line (or a row) are refreshed, and accordingly, both expressions(e.g., refreshing of a word line and refreshing of a row) may be used throughout the present disclosure.

The memory cells may be disturbed by numerous causes, and various operations may be applied to the memory device 200 to secure data reliability. Taking a target refresh operation as an example, when a word line is intensively and/or frequently activated (or accessed), which may be referred to as an aggressor word line, a disturb amount received by memory cells of a word line located in close proximity (e.g., adjacent) to the aggressor word line (hereinafter, referred to as a weak word line) may increase. As a result, a charge change of a cell capacitor of the memory cells connected to the weak word line may occur, and the possibility of data flip may increase as well. To secure the data reliability according to the foregoing phenomenon, a target refresh may be performed with respect to the weak word line non-periodically and/or by certain periods (periodically).

The refresh controller 220 may perform the refresh with respect to the word lines of the memory cell array 210 in response to a refresh command from the memory controller 100. Alternatively or additionally, in a self-refresh mode, the refresh controller 220 may refresh the word lines of the memory cell array 210 without intervention of the memory controller 100. In an embodiment, when a particular word line is intensively (or frequently) accessed, the refresh controller 220 may control the target refresh operation with respect to one or more weak word lines adjacent to the intensively accessed word line based on the control by the control logic 230.

The phenomenon that the weak word line is disturbed due to frequent activation of word line may be referred to as row hammer. The row hammer controller 231 may perform various control operations for securing data reliability against row hammer. For example, the row hammer controller 231 may identify at least one word line that may be activated relatively frequently, based on results of determining activation and/or access counts of the word lines and may identify locations of at least one weak word lines adjacent to a frequently activated word line. Information about the weak word lines may be provided to the refresh controller 220. The refresh controller 220 may selectively perform a normal refresh operation and/or a target refresh operation in response to the refresh command. In an embodiment, the refresh controller 220 may include a scheduler 221, and the scheduler 221 may perform scheduling with respect to the normal refresh operation and the target refresh operation.

When the word line is active, the active word line may have the effect of being refreshed. For example, the active word line may be connected to the sense amplifier circuit 211. The data of the active word line may be stored in the sense amplifier circuit 211, and the amplified data may be restored in the memory cells. In an embodiment, the inversion controller 232 may invert values of data in the process of storing the data stored in the sense amplifier circuit 211 in the memory cells or control inversion of the data values in the process of outputting the data stored in the sense amplifier circuit 211 to the outside. In addition, during the data writing process, data may be written on some of the memory cells connected to the active word line, and the inversion controller 232 may perform the control operation to invert values of write data in the process of writing the write data on the memory cells through the sense amplifier circuit 211.

When taking the aggressor word line and weak word line adjacent thereto as an example, the disturbance characteristics may change according to patterns of data stored in the weak word line and the aggressor word line. For example, the charge loss may be generated differently according to the values of data stored in the memory cell of the weak word line and the memory cell of the aggressor word line that may be affected by the mutual disturbance (e.g., the memory cells connected to the same bit line). When the values of the data stored in the memory cell of the aggressor word line and the data stored in the memory cell of the weak word line are different from each other, the disturb amount may further increase. That is, a worst case of disturbance (e.g., a maximized disturb amount) may occur when the values of the data stored in the memory cell of the aggressor word line and the data stored in the memory cell of the weak word line are different from each other. When the active counting of the aggressor word line increases while the worst case is maintained, the possibility of data flip of the memory cell of the weak word line may further increase.

According to an embodiment of the present disclosure, when the word lines are active, the values of data of the memory cells of the active word lines may be inverted, and the inverted data may be restored in the memory cells. By doing so, the frequency of disturbance applied to the memory cells, while the worst case of data patterns is maintained, may decrease. For example, assuming that the disturb amount of the worst case is represented as S, and the disturb amount of the non-worst case is represented as S/2, when the aggressor word line is activated 2N times in the worst case, the disturb amount of the memory cell of the weak word line may have the value of 2N ×S, where N is a positive integer greater than zero (0). Alternatively, when the embodiments of the present disclosure are applied, under substantially similar and/or the same conditions, the memory cell of the weak word line may be disturb N times in the worst case, and may be disturbed N times in the non-worst case. Accordingly, the accumulated disturb amount applied to the memory cell of the weak word line may decrease to 3/2(N×S).

In an embodiment, the inverting of the data values when the activation is performed may be applied to all word lines of the memory cell array 210. Alternatively, at least one aggressor word line from among all of the word lines of the memory cell array 210 may be identified, and the inverting of the data value during the activation may be applied to the at least one aggressor word line. That is, the inverting of the data values may not be applied to some word lines of the memory cell array 210, and the inverting of the data values may be applied to other word lines of the memory cell array 210.

In an embodiment, an operation of inverting data values every time the activation is performed with respect to the word lines may be performed. Alternatively or additionally, an operation of inverting data values according to certain times of activation period may be performed. That is, embodiments of the present disclosure may be applied differently according to various conditions, and for example, based on various conditions such as, but not limited to, a deterioration degree, an operating environment including temperature, voltage, or the like of the memory device 200, the data inversion operation, according to various embodiments, may be performed with respect to some or all of the word lines, and/or the frequency of performing the data inversion operation may be changed.

The aggressor word line may correspond to a word line that is most frequently activated in a certain section. However, the present disclosure is not limited thereto. The aggressor word line may be determined by various criteria. For example, the aggressor word line may include two (2) or more word lines that have been relatively frequently activated in a certain section and/or include two (2) or more word lines that have been activated more than a reference value (e.g., a threshold). Alternatively or additionally, a word line that has been consecutively activated more than a reference value may be identified as the aggressor word line.

The memory device 200 may be and/or may include a DRAM such as, but not limited to, a double data rate (DDR) synchronous DRAM (DDR SDRAM), a low power DDR (LPDDR) SDRAM, a graphics DDR (GDDR) SDRAM, a Rambus DRAM (RDRAM), or the like. However, embodiments of the present disclosure are not limited thereto. Notably, the embodiments may be applied to a memory device configured to perform a data retention operation corresponding to the refresh, (e.g., non-volatile memory such as, but not limited to, magnetic RAM (MRAM), ferroelectric RAM (FeRAM), phase change RAM (PRAM), resistive RAM (ReRAM), or the like).

The memory device 200 may be a memory chip and/or may be a semiconductor package including two (2) or more memory chips. Alternatively, the memory device 200 may be a memory module in which a plurality of memory chips are mounted on a module board. Although FIG. 1 illustrates the memory controller 100 and the memory device 200 as two (2) separate components, the present disclosure is not limited in this regard. For example, the memory device 200 may be implemented as a memory system in which the memory control function and the memory cell array 210 are integrated into one semiconductor package.

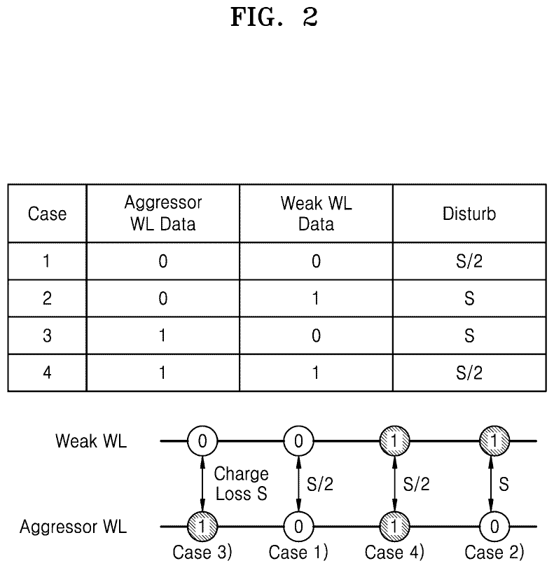

FIG. 2 is a diagram illustrating an example of a disturb amount according to data patterns of an aggressor word line and a weak word line, according to an embodiment. Values illustrated in FIG. 2 are just an example, and the disturb amounts between the memory cells may be different from the values shown in FIG. 2. In addition, the example of FIG. 2 explains a case where each memory cell stores one bit of data. However, the present disclosure is not limited in this regard. For example, aspects of the present disclosure may be applied to cases where each memory cells stores two (2) or more bits of data.

Data of each of the memory cell of the aggressor word line (hereinafter referred to as a first memory cell) and the memory cell of the weak word line (hereinafter referred to as a second memory cell) may have a logic low value (e.g., zero, 0) or a logic high value (e.g., one, 1). As shown in FIG. 2, the disturb amount may change according to the data patterns of the data stored in the memory cells causing mutual disturbance between the aggressor word line and the weak word line. For example, when the values of data are different from each other (e.g., case 2 and case 3), the disturb amount may be represented as S, and when the values of the data the same as each other (e.g., case 1 and case 4), the disturb amount may be represented as S/2.

In Case 1 of FIG. 2, when the first memory cell and the second memory cell stores the logic low value (e.g., “0”), the disturb amount applied to the second memory cell when the first memory cell is active may correspond to S/2, Similarly, in Case 4 of FIG. 2, when each of the first memory cell and the second memory cell stores the logic high value (e.g., “1”), the disturb amount applied to the second memory cell when the first memory cell is active may correspond to S/2. Alternatively or additionally, in Case 2 of FIG. 2, when the first memory cell stores the logic low (e.g., “0”) and the second memory cell stores the logic high value (e.g., “1”), the disturb amount applied to the second memory cell when the first memory cell is active may correspond to S. Similarly, in Case 3 of FIG. 2, when the first memory cell stores the logic high value (e.g., “1”) and the second memory cell stores the logic low value (e.g., “0”) the disturb amount applied to the second memory cell when the first memory cell is active may correspond to S.

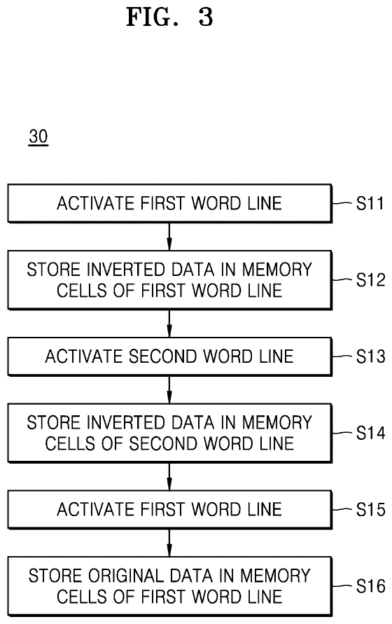

FIG. 3 is a flowchart 30 illustrating an operating method of a memory device, according to an embodiment.

Referring to FIG. 3, the memory cell array 210 may include a plurality of word lines, and the first word line from among the plurality of word lines may be activated in response to the command from the memory controller 100 (operation S11). The data of the memory cells of the active first word line may be stored in the sense amplifier circuit 211, and along with the inversion of the data, the inverted data may be stored in the memory cells of the first word line (operation S12). Accordingly, inverted data of data provided from the memory controller 100 (e.g., original data) may be stored in the memory cells of the first word line.

Similarly, the second word line may be activated in response to the command from the memory controller 100 (operation S13). The data of the memory cells of the active second word line may be stored in the sense amplifier circuit 211, and along with the inversion of the data, the inverted data may be stored in the memory cells of the second word line (operation S14). Accordingly, inverted data of the original data provided from the memory controller 100 may be stored in the memory cells of the second word line.

In addition, the first word line may be reactivated in response to the command from the memory controller 100 (operation S15). The data of the memory cells of the active first word line may be stored in the sense amplifier circuit 211, and along with the inversion of the data, the inverted data may be stored in the memory cells of the first word line (operation S16). Accordingly, data having the same value as the original data provided from the memory controller 100 may be stored in the memory cells of the first word line.

According to the operating method described with reference to flowchart 30, the original data provided from the memory controller 100 may be stored in some of the plurality of word lines of the memory cell array 210, which may be construed as data of a first polarity (e.g., a positive polarity) being stored. Alternatively, inverted data of the original data provided from the memory controller 100 may be stored in other word lines from among the plurality of word lines, which may be construed as data of a second polarity (e.g., a negative polarity) being stored.

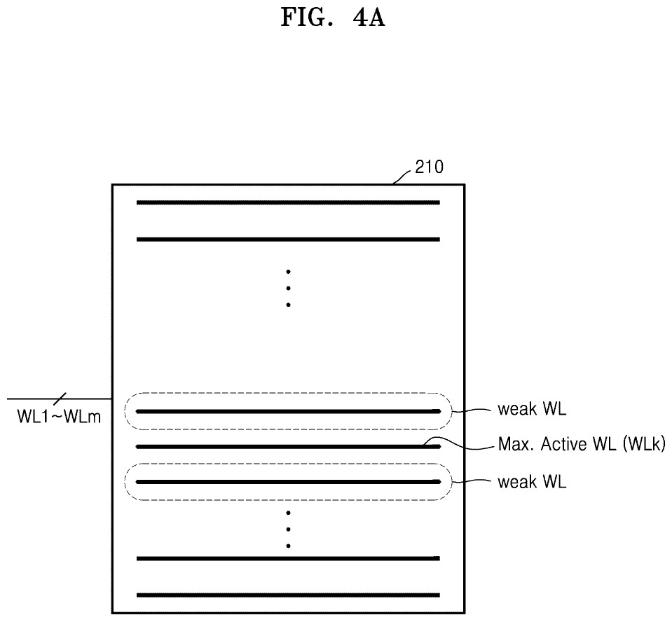

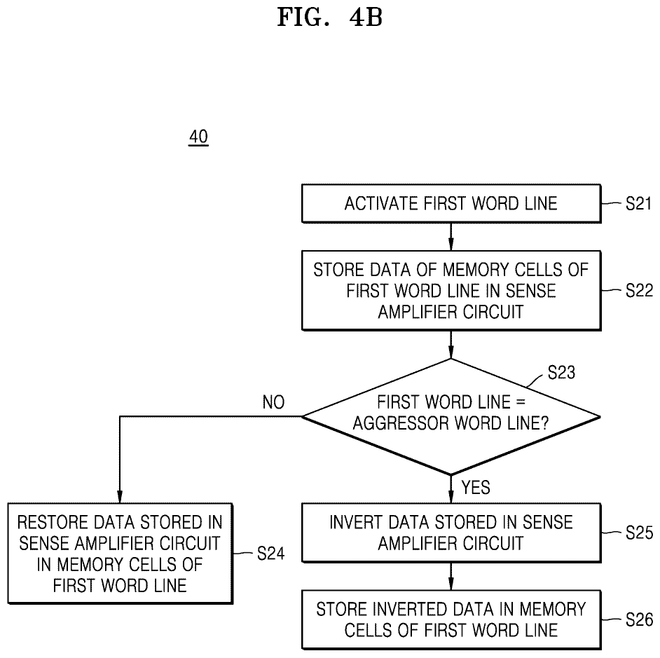

FIGS. 4A and 4B illustrate an operating method of a memory device 200, according to an embodiment.

Referring to FIG. 4A, the memory cell array 210 may include a plurality of word lines (e.g., a first word line WL1 to an m-th word line WLm, where m is a positive integer greater than one (1)), and a word line that is most frequently activated in a certain period may be identified (e.g., a k-th word line, where k is a positive integer greater than zero (0) and less than or equal to m). When the k-th word line WLk is identified as the most active word line, the k-th word line may correspond to the aggressor word line, and one or more word lines adjacent to the k-th word line WLk may correspond to the weak word lines (e.g., a (k−1)-th word line and a (k+1)-th word line). Although FIG. 4A illustrates an example in which the weak word lines are respectively located on both sides of the k-th word line WLk (e.g., a (k−1)-th word line and the (k+1)-th word line), the present disclosure is not limited to in this regard. For example, the weak word lines may be located on one side of the k-th word line WLk, and/or the weak word lines may include two (2) or more word lines respectively located on both sides of the k-th word lines. In addition, although FIG. 4A illustrates that one word line may be identified as the aggressor word line, based on counting results, two (2) or more word lines may be identified as the aggressor word line.

In various embodiments, a target refresh may be performed with respect to the weak word lines, and/or a normal refresh may be performed with respect to the normal (e.g., active) word lines in response to the command from the memory controller 100. When the data retention characteristics of the memory cells are deteriorated, and/or the number of active word lines increases, the frequency of the normal refresh and/or the target refresh performed with respect to the word lines may need to increase, which may cause degradation of operational performance of a memory device 200. However, according to the embodiments of the present disclosure, based on the inverting of the data of the memory cells of the word lines, the frequency of disturbance applied to the memory cells may decrease, even if the worst case of the data pattern is maintained, and thereby, an increase in the frequency of refresh may be prevented or reduced, along with a possible improvement of data retention characteristics.

Referring to FIG. 4B, a flowchart 40 illustrating an operating method of a memory device 200, according to an embodiment. As shown in FIG. 4B, the first word line may be activated in response to the command from the memory controller 100 (operation S21). In addition, the data of the memory cells of the active first word line may be stored in the sense amplifier circuit 211 (operation S22). The first word line may be identified as an the aggressor word line based on a counting value that represents the counts (e.g., a number of times) that the first word line has been activated (operation S23). When the first word line is not the aggressor word line (NO in operation S23), the data stored in the sense amplifier circuit 211 may be restored in the memory cells of the first word line without inversion of the data of the memory cells of the first word line (operation S24).

Alternatively, when the first word line corresponds to the aggressor word line (YES in operation S23), the inversion may be performed with respect to the data stored in the sense amplifier circuit 211 (operation S25), and the inverted data may be stored in the memory cells of the first word line (operation S26).

According to the embodiments illustrated in FIGS. 4A and 4B, without applying the data inversion to all word lines of the memory cell array 210, the data inversion may be applied only to some of the word lines, which may have a relatively high probability of data flip, and accordingly, a frequency of performing the data inversion processing may decrease, as well as, reducing a possible negative impact to the performance of the memory device.

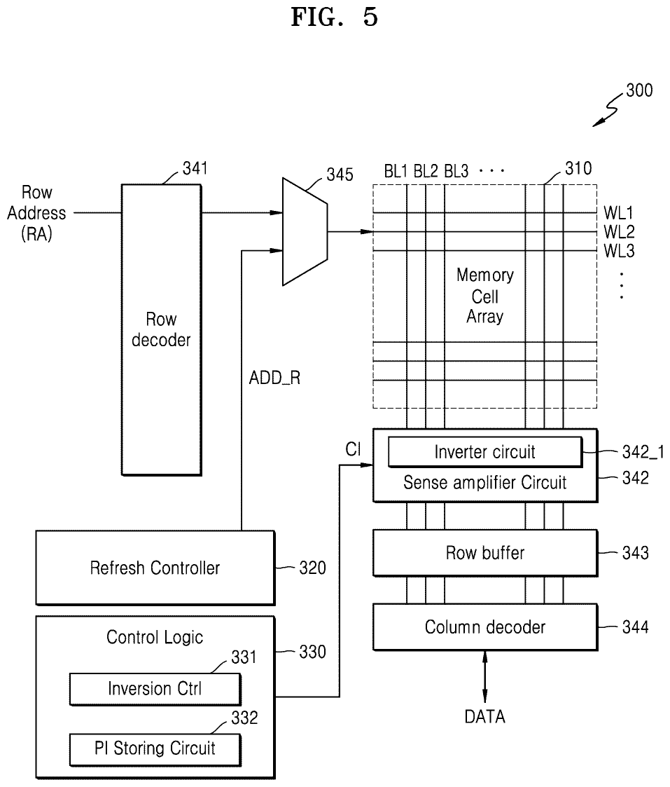

FIG. 5 is a block diagram illustrating an example of a memory device, according to an embodiment.

Referring to FIG. 5, a memory device 300 may include a memory cell array 310, a refresh controller 320, and a control logic 330. In addition, the memory device 300 may include various peripheral circuits relating memory operations of the memory cell array 310, and the memory device 300 may further include, for example, a row decoder 341, a sense amplifier circuit 342, a row buffer 343, a column decoder 344, and a selector 345.

The memory device 300 may include and/or may be similar in many respects to the memory device 200 described above with reference to FIGS. 1 to 4B, and may include additional features not mentioned above. Furthermore, the memory cell array 310, the sense amplifier circuit 342, the refresh controller 320, and the control logic 330 may respectively include and/or may be similar in many respects to the memory cell array 210, the sense amplifier circuit 211, the refresh controller 220, and the control logic 230 described above with reference to FIG. 1, and may include additional features not mentioned above. Consequently, repeated descriptions of the memory device 300 and its components described above with reference to FIGS. 1 to 4B may be omitted for the sake of brevity.

An address for data access may be received from the memory controller 100, and the address may include a row address RA indicating a row of the memory cell array 310. The row decoder 341 may activate a word line of the memory cell array 310 (e.g., a first word line WL1, a second word line WL2, a third word line WL3, or the like) corresponding to the row address RA, and data of the active word line may be stored and amplified in the sense amplifier circuit 342, which may be obtained by activating bit lines of the memory cell array 310 (e.g., a first bit line BL1, a second bit line BL2, a third bit line BL3, or the like). In addition, the data sensed by the sense amplifier circuit 342 may be temporarily stored in the row buffer 343, and the data stored in the row buffer 343 may be provided to the memory controller 100 through the column decoder 344.

When the refresh command is received from the memory controller 100, the refresh controller 320 may output a refresh address ADD_R indicating a word line on which the normal refresh or the target refresh is to be performed. For example, the refresh controller 320 may generate an address indicating a word line on which the normal refresh is to be performed based on the counting operation and selectively output an address for the normal refresh or an address indicating a weak word line according to the refresh scheduling. The selector 345 may output the row address RA from the memory controller 100 during the normal memory operation such as, but not limited to, writing, reading, or the like, and may output the refresh address ADD_R during the refresh operation.

In an embodiment, the memory device 300 may include an inverter circuit 342_1. Although FIG. 5 illustrates the inverter circuit 342_1 as being arranged in the sense amplifier circuit 342, the present disclosure is not limited in this regard. For example, the inverter circuit 342_1 may be arranged outside of the sense amplifier circuit 342. The inverter circuit 342_1 may include at least some of inverters configured to invert values of data in the process of storing the data stored in the sense amplifier circuit 342 in the memory cell array 310, inverters configured to invert values of data in the process of outputting the data read from the memory cell array 310 to the outside through the column decoder 344, and inverters configured to invert values of data in the process of providing the write data to the memory cell array 310 through the sense amplifier circuit 342.

An inversion controller 331 may perform a control operation for inverting values of data, according to an embodiment. The inversion controller 331 may provide control signals CI to the inverter circuit 342_1. For example, the data read/write operation may include an active section, a read/write section, and a precharge section, and the inversion controller 331 may provide activated control signals CI in the section for inversion of data values to the inverter circuit 342_1.

The control logic 330 may include a polarity information (PI) storing circuit 332 storing a flag including the polarity information PI of each word line of the memory cell array 310. For example, when the memory cells of the word line store data of the first polarity having the same values as the data provided from the memory controller 100, the flag corresponding to the word line may have a first value (e.g., logic low value, zero, “0”). Alternatively, when the memory cells of the word line store data of the second polarity having the inverted values of the data provided from the memory controller 100, the flag corresponding to the word line may have a second value (e.g., logic high value, one, “1”).

During the reading and writing of the memory device 300, the inversion controller 331 may control the data inversion based on the flag stored in the PI storing circuit 332. For example, when taking a read operation as an example, upon reception of the read request with respect to the first word line, the inversion controller 331 may check the flag corresponding to the first word line, and when the flag has the first value, the inversion may not be performed on the data read from the first word line. Alternatively, when the flag corresponding to the first word line has the second value, the inversion controller 331 may control the inversion processing such that the values of the data read from the first word line are inverted and output to the memory controller 100.

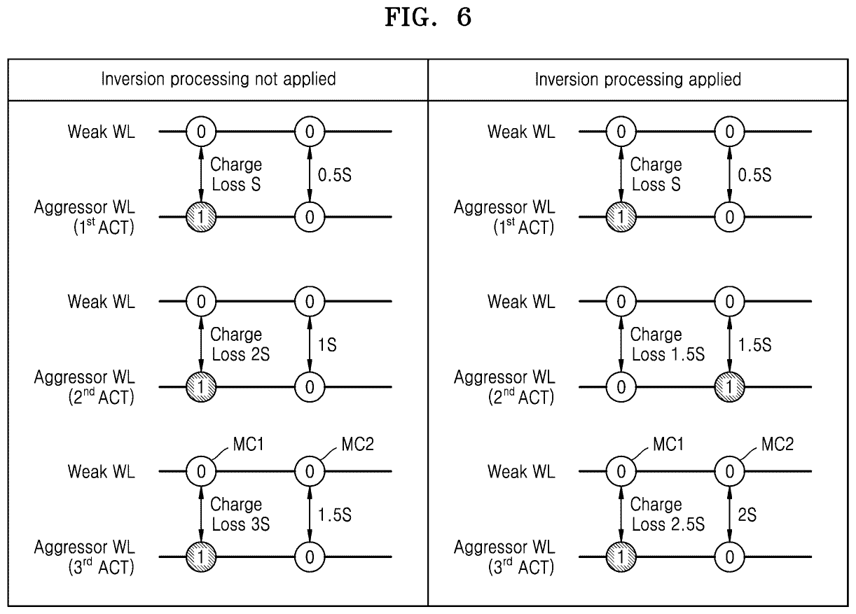

FIG. 6 is a diagram illustrating an accumulated disturb amount depending on application of inversion processing, according to an embodiment. The active word line may be assumed to be the aggressor word line, and the disturbed word line may be assumed to be the weak word line. The disturbances between the memory cell of the aggressor word line and the memory cell of the weak word line that are connected to the same bit line are described.

Referring to FIG. 6, when the activation of the aggressor word line is repeatedly performed, the accumulated disturb amount applied to the memory cells of the weak word line may increase. However, as shown in FIG. 6, application of inversion processing may reduce the amount of accumulated disturb amount applied to the memory cells.

FIG. 6 illustrates the accumulated disturb amounts (e.g., charge losses) for two memory cells (e.g., a first memory cell MC1 and a second memory cell MC2) as the memory cells are repeatedly activated a total of three (3) times (e.g., a first activation (ACT), a second activation, and a third activation). The first memory cell MC1 represents a worst case in which the data value of the memory cell of the weak word line and the data value of the memory cell of the aggressor word line are different from each other, and the second memory cell MC2 represents another case in which the data value of the memory cell of the weak word line and the data value of the memory cell of the aggressor word line are the same.

Referring to a scenario where the inversion processing is not applied (e.g., left column of FIG. 6), the disturb amount (e.g., charge loss) applied to the first memory cell MC1 when the first activation is performed with respect to the aggressor word line may correspond to S, and the disturb amount applied to the second memory cell MC2 when the first activation is performed with respect to the aggressor word line may correspond to 0.5S (e.g., ½×S). The disturb amount may proportionally increase as the activation is repeated. For example, when the second activation is performed with respect to the aggressor word line, the accumulated disturb amount of the first memory cell MC1 may correspond to 2S (e.g., 2×S), and the accumulated disturb amount of the second memory cell MC2 may correspond to S (e.g., 1×S). As another example, when the third activation is performed with respect to the aggressor word line, the accumulated disturb amount of the first memory cell MC1 may correspond to 3S (e.g., 3×S), and the accumulated disturb amount of the second memory cell MC2 may correspond to 1.5S (e.g., 1½×S). That is, when inversion processing is not applied, the total accumulated disturb amount after three (3) activations on the first memory cell MC1 and the second memory cell MC2 may respectively correspond to 3S and 1.5S.

Alternatively, referring to a scenario where the inversion processing is applied (e.g., right column of FIG. 6), the disturb amount applied to the first memory cell MC1 and the second memory cell MC2, when the first activation is performed with respect to the aggressor word line, may correspond to S and 0.5S, respectively. The disturb amount applied to the first memory cell MC1 and the second memory cell MC2 may respectively increase to 1.5S and 1.5S, after the second activation is performed with respect to the aggressor word line. The total accumulated disturb amount after three (3) activations on the first memory cell MC1 and the second memory cell MC2 may respectively correspond to 2.5S and 2S.

According to the example scenarios illustrated in FIG. 6, when the inversion processing is not applied, as the aggressor word line is frequently activated in the worst case of data pattern, the disturb amount of the first memory cell MC1 may increase significantly, and accordingly, the probability of a data flip of the first memory cell MC1 may increase. However, when the inversion processing is applied, according to various embodiments, the frequency of disturbance applied to the first memory cell MC1 in the worst case may decrease, and accordingly, the total disturb amount applied to the first memory cell MC1 may be reduced. That is, according to aspects of the present disclosure, the disturb amount applied to the memory cells may be evenly distributed among the memory cells, and the deviation of the data retention characteristics of the memory cells may decrease. Accordingly, when the refresh cycle is set based on memory cells having poor data retention characteristics, the refresh frequency may increase. Additionally, the refresh frequency may decrease, and the degradation of operational performance of a memory device may be reduced or prevented, when compared to a related memory device.

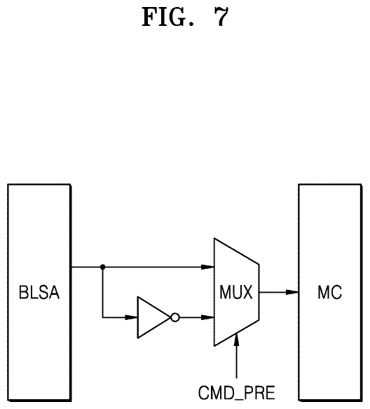

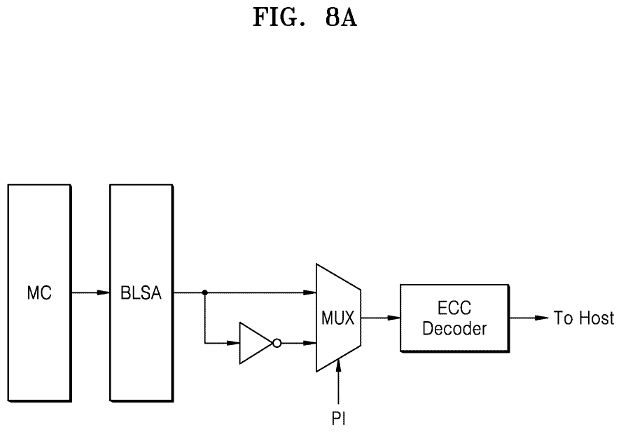

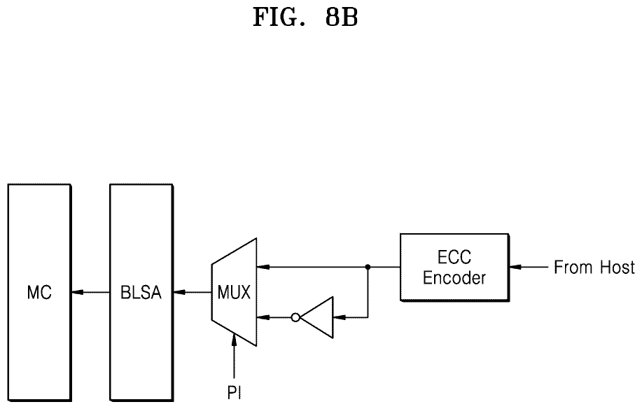

FIGS. 7, 8A, and 8B are each a diagram illustrating an example of inversion processing of data values in various memory operations, according to some embodiments. FIGS. 7, 8A, and 8B illustrate a bit line sense amplifier BLSA connected to one memory cell MC and an error correction code (ECC) encoder and an ECC decoder that respectively perform ECC encoding and decoding of data.

Referring to FIG. 7, the bit line connected to the memory cell MC may be precharged to a certain precharge level, and when the word line connected to the memory cell MC is active, charge sharing may be performed between the bit line and the cell capacitor of the memory cell MC. When the data stored in the memory cell MC is logic low, the charges of the bit line may move to the cell capacitor of the memory cell MC, and the voltage level of the bit line may be lowered. Alternatively, when the data stored in the memory cell MC is logic high, the charges of the memory cell MC may move to the bit line, and the voltage level of the bit line may increase.

The data read from the memory cell MC and stored in the bit line sense amplifier BLSA may be restored in the memory cell MC, or the data to be written on the memory cell MC may be stored in the memory cell MC through the bit line sense amplifier BLSA. In addition, when a memory operation such as, but not limited to, reading, writing, or the like is completed, a precharge command CMD_PRE for changing the voltage level to the precharge level may be provided to the memory device 300. For example, when the word line is active by the active command, after the active command is received, the precharge command CMD_PRE may be received after a predetermined time period.

In an embodiment, before performing the precharge operation with respect to the bit line in response to the precharge command CMD_PRE, the memory device 300 may invert values of data stored in the bit line sense amplifier BLSA and store the same in the memory cell MC or invert values of write data and store the same in the memory cell MC. For example, a selector MUX may receive and selectively output data from the bit line sense amplifier BLSA or may selectively output data having inverted values to the memory cell MC in response to the precharge command CMD_PRE.

FIG. 8A is a diagram illustrating an example of inversion processing of data in the process of reading the data, according to an embodiment.

Referring to FIG. 8A, according to the active command from the memory controller 100, the data of the memory cell MC may be stored in the bit line sense amplifier BLSA, and in response to the reception of the read command, the memory device 300 may amplify the data stored in the bit line sense amplifier BLSA and output the amplified data to the memory controller 100. The polarity information PI of the word line connected to the memory cell MC may be identified, and the selector MUX may selectively output data stored in the bit line sense amplifier BLSA or data having inverted values thereof based on the polarity information PI. When the polarity information PI of the word line has the first value, the value of the data stored in the memory cell MC may be identified as being identical to the value of the original data, and the selector MUX may select and output the data stored in the bit line sense amplifier BLSA. Alternatively, when the polarity information PI of the word line has the second value, the value of the data stored in the word line may be identified as being inverted from the original data, and the selector MUX may select and output the data having the inverted value of the data stored in the bit line sense amplifier BLSA. In addition, the data output from the selector MUX may be output to the host through the ECC decoder.

FIG. 8B is a diagram illustrating an example of inversion processing of data in the process of writing the data, according to an embodiment.

Referring to FIG. 8B, according to the active command from the memory controller 100, the word line connected to the memory cell MC may become active, and the write data from the host may be provided to the bit line sense amplifier BLSA through the ECC encoder. The polarity information PI of the word line connected to the memory cell MC may be identified, and the selector MUX may output the data from the ECC encoder to the bit line sense amplifier BLSA or output the data having the inverted value of the data from the ECC encoder to the bit line sense amplifier BLSA, based on the polarity information PI. For example, the polarity information of the word line has the first value, the selector MUX may output the write data to the bit line sense amplifier without inverting the write data. Alternatively, when the polarity information PI of the word line has the second value, the selector MUX may select the data having the inverted value of the write data and output the same to the bit line sense amplifier BLSA. The data provided to the bit line sense amplifier BLSA may be written on the memory cell MC.

As shown in FIGS. 8A and 8B, the data read and/or write operation may involve the active operation of the word line, and as the polarity of data of memory cells of a frequently active word line may change every time of activation, the frequency of disturbance applied to the memory cells in the worst case of data pattern may decrease, and the data retention characteristics of the memory cells may be improved, when compared to related memory device.

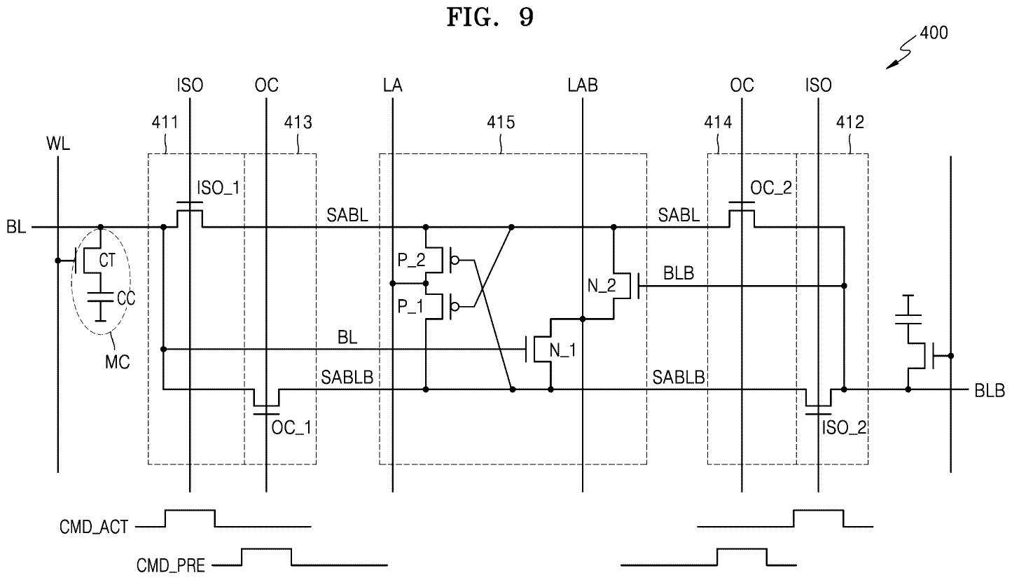

FIG. 9 is a circuit diagram illustrating an example of a bit line sense amplifier 400, according to various embodiments. FIG. 9 illustrates an example in which the value of data stored in the memory cell MC is inverted based on configuration of a bit line BL and a complementary bit line BLB to which a complementary level is applied without a separate inverter for inverting the value of the data stored in the bit line sense amplifier 400. The complementary bit line BLB may be a bit line connected to a memory cell adjacent to the memory cell MC (e.g., a memory cell of an adjacent word line).

Referring to FIG. 9, the memory cell MC may include a cell transistor CT and a cell capacitor CC. The bit line sense amplifier 400 may include a first isolator 411, a second isolator 412, a first offset remover 413, a second offset remover 414, and an amplifier 415. The first isolator 411 may be connected between the bit line BL and a sensing bit line SABL, and the second isolator 412 may be connected between the complementary bit line BLB and a complementary sensing bit line SABLB. The first and second isolators 411 and 412 may operate in response to an isolation signal ISO.

The first isolator 411 may include a first isolation transistor ISO_1 configured to electrically connect the bit line BL with the sensing bit line SABL or cut off the bit line BL from the sensing bit line SABL in response to the isolation signal ISO. The second isolator 412 may include a second isolation transistor ISO_2 configured to electrically connect the complementary bit line BLB with the complementary sensing bit line SABLB or cut off the complementary bit line BLB from the complementary sensing bit line SABLB in response to the isolation signal ISO.

The first and second offset remover 413 and 414 may receive an offset remove signal OC and operate in response to the offset remove signal OC. The first offset remover 413 may include a first offset remove transistor OC_1 configured to electrically connect the bit line BL with the complementary sensing bit line SABLB or cut off the bit line BL from the complementary sensing bit line SABLB in response to the offset remove signal OC. The second offset remover 414 may include a second offset remove transistor OC_2 configured to electrically connect the complementary bit line BLB with the sensing bit line SABL or cut off the complementary bit line BLB from the sensing bit line SABL in response to the offset remove signal OC.

The amplifier 415 may include a plurality of transistors (e.g., a first PMOS transistor P_1, a second PMOS transistor P_2, a first NMOS transistor N_1, and a second NMOS transistor N_2) that are connected between the sensing bit line SABL and the complementary sensing bit line SABLB. The amplifier 415 may sense and amplify a voltage difference between the complementary sensing bit line SABLB and the sensing bit line SABL according to first and second control signals LA and LAB. For example, according to the value of data stored in the memory cell MC, the voltage of the sensing bit line SABL and the complementary sensing bit line SABLB may be developed, and according to the amplification operation of the amplifier 415, the data stored in the bit line sense amplifier 400 may be amplified.

In an embodiment, as the first and second isolators 411 and 412 are turned on in response to the active command CMD_ACT, the data of the memory cell MC may be stored and amplified in the bit line sense amplifier 400. The voltage applied to the sensing bit line SABL connected to the bit line BL may correspond to the voltage level corresponding to the logic value of the data of the memory cell MC, and the voltage applied to the complementary sensing bit line SABLB connected to the complementary bit line BLB may correspond to the voltage level corresponding to the inverted value of the logic value of the data of the memory cell MC.

In an embodiment, when inverting a data value, the first and second isolators 411 and 412 may be turned off, and the first and second offset removers 413 and 414 may be turned on in response to the precharge command CMD_PRE. The data having the inverted value of the data restored in the bit line sense amplifier 400 may be stored in the memory cell MC. For example, when the first and second offset removers 413 and 414 are turned on, the memory cell MC may be electrically connected to the complementary sensing bit line SABLB, and the data having the logic value corresponding to the voltage level of the complementary sensing bit line SABLB may be stored in the memory cell MC. After the inverted data is stored, the sensing bit line SABL and the complementary sensing bit line SABLB may be electrically connected to each other based on an operation of a precharge circuit, and the bit line BL may be precharged to a certain precharge level.

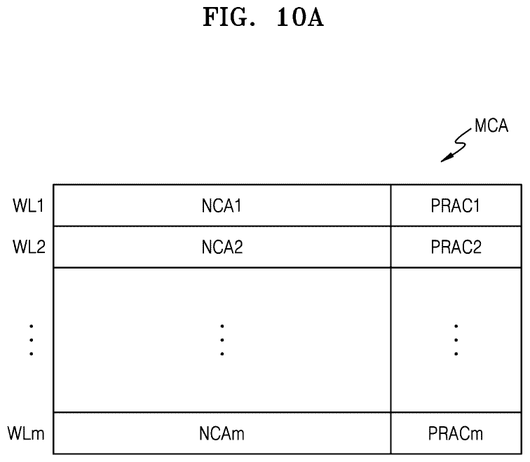

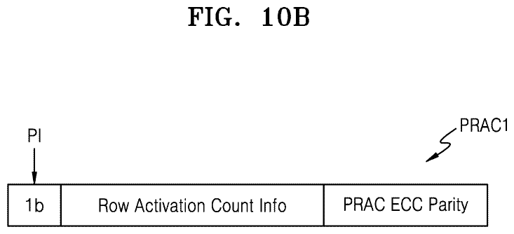

FIGS. 10A and 10B are each a diagram illustrating an example in which polarity information is stored, according to some embodiments.

Referring to FIG. 10A, when the memory device 300 supports per-row activation counting (PRAC), the memory device 300 may further include PRAC cells storing PRAC information including activation counting of the word lines of the memory cell array 310, in addition to the normal memory cells storing normal data such as, but not limited to, user data, or the like. For example, the memory cell array MCA may include a normal cell area and a PRAC cell area in correspondence to each word line, and the PRAC cell area may include a plurality of PRAC cells. FIG. 10A illustrates an example in which the memory cell array MCA includes a plurality of word lines (e.g., a first word line WL1, a second word line WL2, to an m-th word line WLm, where m is a positive integer greater than one (1)), a plurality of normal cell areas (e.g., a first normal cell area NCA1, a second normal cell area NCA2, to an m-th normal cell area NCAm), and a plurality of PRAC cell areas (e.g., a first PRAC cell area PRAC1, a second PRAC cell area PRAC2, to an m-th PRAC cell area PRACm). A memory system that supports PRAC may determine the activation counting performed with respect to each word line based on the PRAC information stored in the PRAC cell areas of the memory device 300 and may secure data reliability by performing an operation such as, but not limited to, temporary suspension of excessive traffic with respect to the memory system, when excessive activation counting is sensed.

FIG. 10B is a diagram illustrating an example of PRAC information stored in PRAC cells, according to an embodiment. In an embodiment, the PRAC cells of FIG. 10A may include a first PRAC cell area PRAC1 corresponding to the first word line. As shown in FIG. 10B, the first PRAC cell area PRAC1 may include a field consisting of a group of PRAC cells storing row activation counting information and another field consisting of another group of PRAC cells storing PRAC ECC parity information for performing error detection/correction of the PRAC information. In addition, the first PRAC cell area PRAC1 may further include at least one PRAC cell storing a flag indicating the polarity information PI, according some embodiments. For example, when the flag includes one bit, one PRAC cell storing the flag may be included in the first PRAC cell area PRAC1.

According to the embodiments described above, in a read and/or write operation of data, when the first word becomes active, the PRAC information stored in the first PRAC cell area PRAC1 may be read. The memory device 300 may perform inversion of data based on the flag included in the PRAC information and may update row activation counting increased by one (1) from the activation counting of the first word line to the first PRAC cell area PRAC1.

Although FIG. 10B depicts, for ease of description, an example of the PRAC information stored in the first PRAC cell area PRAC1, the present disclosure is not limited in this regard. For example, the first PRAC cell area PRAC1 may contain other fields and/or the fields may be organized in a different order. In addition, the remaining PRAC cell areas (e.g., the second PRAC cell area PRAC2 to the m-th PRAC cell area PRACm may have a same arrangement of fields as depicted in FIG. 10B, or may have a different configuration.

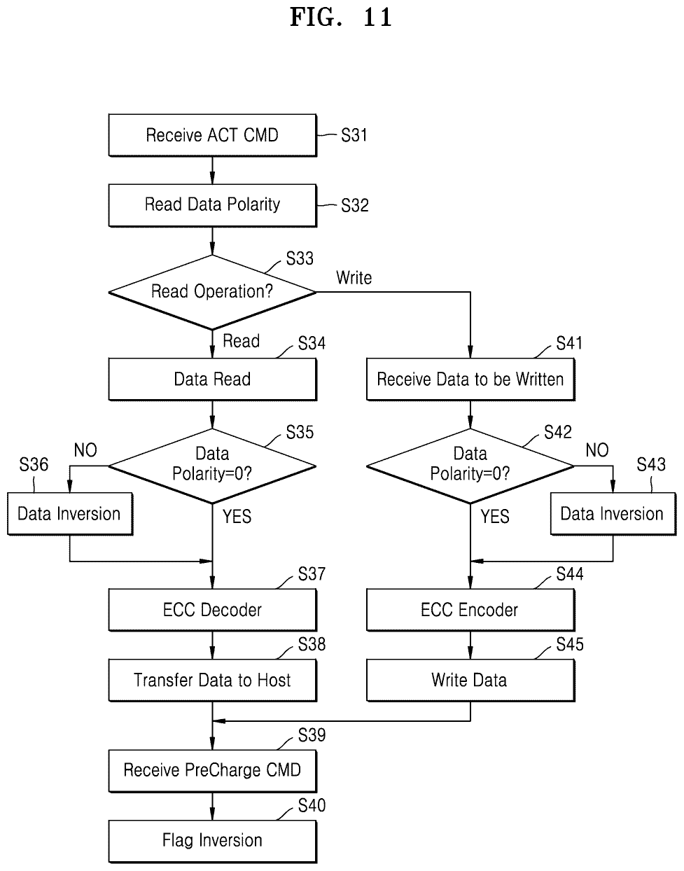

FIG. 11 is a flowchart illustrating a specific example of an operating method of a memory device 300, according to an embodiment.

Referring to FIGS. 10A, 10B, and 11, the memory device 300 may receive an active command with respect to the first word line (operation S31) and read polarity information from PRAC cells corresponding to the first word line (operation S32). When the flag showing the polarity information has the logic low value, the flag may indicate that the data stored in the memory cells of the first word line corresponds to the original data provided from the host. Alternatively, when the flag has the logic high value, the flag may indicate that the data stored in the memory cells of the first word line corresponds to the inverted data of the original data provided from the host.

The command provided from the memory controller 100 may be identified whether it is a command requesting the read operation (operation S33), and when the command is for the read command (Read in operation S33), the data from the memory cells of the first word line may be read (operation S34). The polarity information may be identified whether it corresponds to the logic low value (YES in operation S35). When the polarity information does not correspond to the logic low value (NO in operation S35), the data read from the memory cells of the first word line may be inverted (operation S36).

Based on the operations described above, the data read from the memory cells of the first word line or the inverted data thereof may be provided to the ECC decoder and then decoded (operation S37). The error-corrected data corresponding to the original data may be transmitted to the host (operation S38), and the memory device 300 may store the data having the inverted value of the data stored in the sense amplifier circuit 342 in the memory cells of the first word line in response to the reception of the precharge command (operation S39). As the value of the data stored in the sense amplifier circuit 349 is inverted, and inverted data is stored in the memory cells of the first word line, the flag value showing the polarity information may be inverted and updated (operation S40).

When the command provided from the memory controller 100 is to request a write operation (Write in operation S33), the write data to be written to the memory cells of the first word line may be received from the host (operation S41). The polarity information may be identified whether it corresponds to the logic low value (YES in operation S42). When the polarity information does not correspond to the logic low value (NO in operation S42), the write data may be inverted (operation S43). Based on the operations described above, the write data or the inverted write data may be provided to the ECC encoder and then encoded (operation S44), and the encoded data may be provided to the memory cells of the first word line through the sense amplifier circuit 342 and written to the memory cells of the first word line (operation S45).

The unit of writing may correspond to the size of some of the memory cells of the word line. Accordingly, when the first word line is active, some of the data stored in the sense amplifier circuit 342 may be the write data provided from the host (or the inverted write data) whereas the other may be data read from the memory cells of the first word line. In some embodiments, after the data is written to the memory cells of the first word line in the basis of writing unit, the value of the data may be inverted by the unit of the memory cells connected to the first word line and then restored in the memory cells.

Accordingly, as in the read operation, the memory device 300 may store the data having the inverted value of the data stored in the sense amplifier circuit 342 in the memory cells of the first word line in response to the reception of the precharge command (operation S39). When the value of the data stored in the sense amplifier circuit 342 is stored in the memory cells of the first word line, the flag value showing the polarity information may be inverted and updated (operation S40).

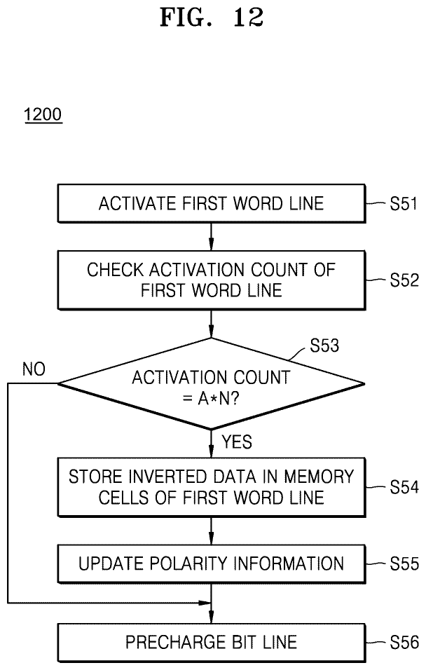

FIG. 12 is a flowchart 1200 illustrating an operating method of a memory device, according to an embodiment.

Referring to FIG. 12, in response to the command from the memory controller 100, the first word line from among the plurality of word lines may become active (operation S51), and the activation counting of the first word line may be identified through the PRAC information stored in the PRAC cells or the storage circuit storing the activation counting information. In an embodiment, when each word line becomes active certain times (e.g., A times, where A is positive integer greater than one (1)), the value of the data stored in the memory cells of the word line may be inverted. In the example of FIG. 12, the value of A may be preset, and N may correspond to a positive integer greater than zero (0). For example, when each word lines becomes active three (3) times, and the value of the data is inverted, the value of A may correspond to three (3), and when the activation counting of the first word line corresponds to a multiple of three (3), the value of the data stored in the memory cells of the first word line may be inverted.

The activation counting of the first word line may be identified whether it corresponds to A×N (operation S53), and when it does (YES in operation S53), the memory device 300 may store the inverted data of the value of the data stored in the sense amplifier circuit 342 in the memory cells of the first word line (operation S54). In addition, the memory device 300 may update and store the polarity information (operation S55), and after the inverted data is stored in the memory cells, the precharge operation may be performed with respect to the bit lines (operation S56). When the activation counting of the first word line does not correspond to A×N (NO in operation S53), the precharge operation may be performed with respect to the bit lines without inversion of the data stored in the sense amplifier circuit 342 or updating of the polarity information (operation S56).

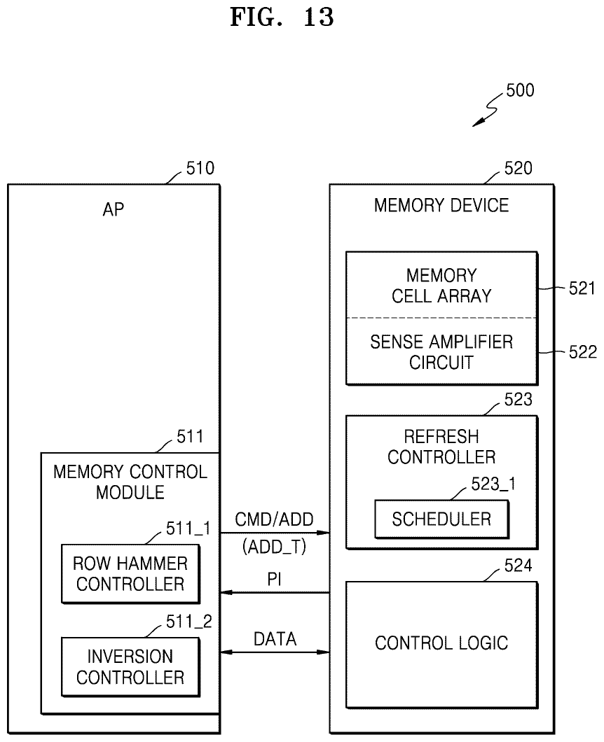

FIG. 13 is a block diagram of a memory system, according to an example embodiment. In the example of FIG. 13, a memory system 500 may include an application processor 510 and a memory device 520, or the memory device 520 and a memory control module 511 in the application processor 510 may constitute the memory system 500. The memory control module 511 may output the command/address CMD/ADD to the memory device 520 and receive and transmit the data DATA. In the embodiment described above, the memory device 520 may include a memory cell array 521, a sense amplifier circuit 522, a refresh controller 523, and a control logic 524, and the refresh controller 523 may include a scheduler 523_1.

The memory device 520 may include and/or may be similar in many respects to the memory device 200 or the memory device 300 described above with reference to FIGS. 1 to 12, and may include additional features not mentioned above. Furthermore, the memory cell array 521, the sense amplifier circuit 522, the refresh controller 523, and the control logic 524 may respectively include and/or may be similar in many respects to the memory cell arrays 210 and 310, the sense amplifier circuits 211 and 342, the refresh controllers 220 and 320, and the control logics 230 and 330 described above with reference to FIGS. 1 to 12, and may include additional features not mentioned above. Consequently, repeated descriptions of the memory device 300 and its components described above with reference to FIGS. 1 to 12 may be omitted for the sake of brevity.

The application processor 510 may be implemented as a system-on-chip (SoC). The SoC may include a system bus to which a protocol having certain standard bus criteria is applied and may conform with one or more known standard protocols. For example, the applied standard bus criteria may include, but not be limited to, an advanced microcontroller bus architecture (AMBA®) protocol of Advanced RISC Machine (ARM®). The bus type of the AMBA® protocol may include, but not be limited to, advanced high-performance bus (AHB), advanced peripheral bus (APB), advanced extensible interface (AXI), AXI4, AXI coherency extensions (ACE), or the like. Alternatively or additionally, the system bus may conform with other types of protocols such as, but not limited to, uNetwork of SONICs Inc., CoreConnect of IBM, open core protocol (OCP) of OCP International Partnership (OCP-IP), or the like. The memory controller 100 or the host described in the embodiments above may be implemented in the form of the application processor 510 illustrated in FIG. 13.

In some embodiments, at least some of various control operations for responding to the row hammer may be performed by the application processor 510. For example, the memory control module 511 may include a row hammer controller 511_1 and an inversion controller 511_2. In addition, in some embodiments, the memory cell array 521 may include PRAC cells. The memory control module 511 may update to the PRAC cells information showing activation counting of the word lines every time the activation is performed with respect to the memory cell array 521.

The row hammer controller 511_1 may determine the activation counting of the word lines based on the PRAC information stored in the PRAC cells and may perform one or more operations such as, but not limited to, the target refresh, or the like based on the activation counting. For example, the memory control module 511 may provide a target address ADD_T showing a location of a word line to which the target refresh is to be performed to the memory device 520.

The inversion controller 511_2 may control the inversion processing of the write data provided to the memory cells of the word lines and/or the data read from the memory cells of the word lines, according to various embodiments. In some embodiments, the memory control module 511 may receive the polarity information PI included in the PRAC information read from the PRAC cells and may determine the polarity of the data stored in the memory cells of each word line based on the polarity information PI. For example, the memory control module 511 may or may not perform the inversion processing of the read data according to the polarity information PI of the data read from the first word line. In addition, the memory control module 511 may receive the polarity information PI corresponding to the first word line, and invert and output the value of the write data to be written on the memory cells of the first word line or output the value of the write data without inversion according to the polarity information PI.

In some embodiments, the value of the data stored in the sense amplifier circuit 522 may be inverted and stored in the memory cells connected to the word line every time the word line becomes active, and in an embodiment, the memory device 520 may include inverters configured to invert the value of the data stored in the sense amplifier circuit 522 or may invert the value of the data stored in the memory cells by controlling the switching operation of the bit line sense amplifier, according to various embodiments described with reference to FIG. 9.

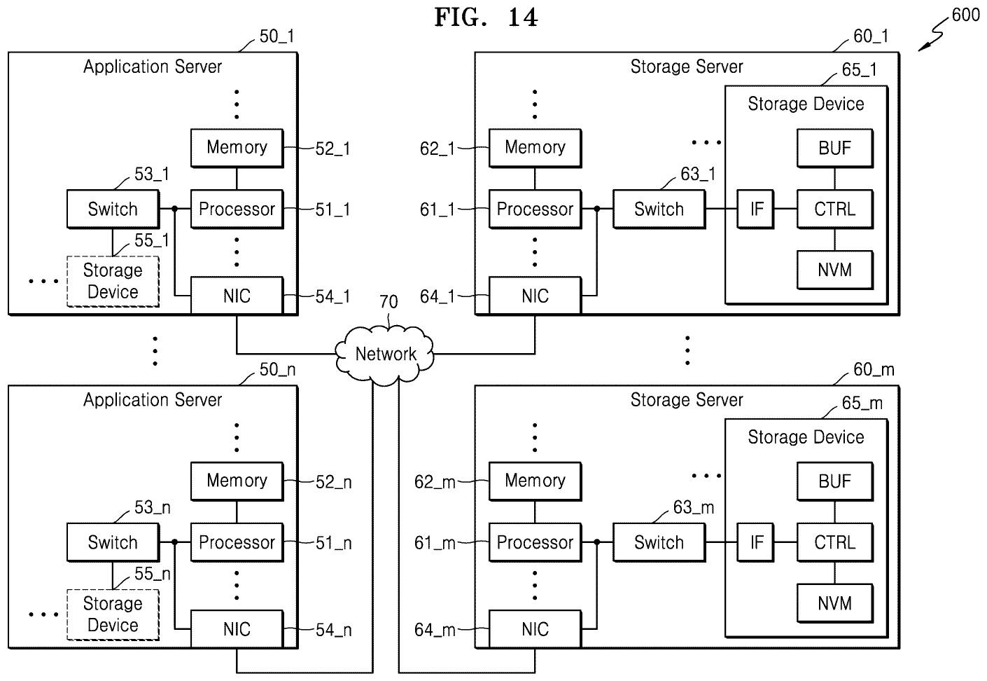

FIG. 14 is a block diagram illustrating a data center 600 including a system, according to an embodiment. In some embodiments, the memory system described in relation to the drawings may be included in an application server and/or a storage server of the data center 600.

Referring to FIG. 14, the data center 600 may collect various data and provide a service and may be referred to as a data storage center. For example, the data center 600 may be and/or may include a system for a search engine and database operation and/or may be and/or may include a computing system used in an enterprise such as, but not limited to, a bank, a government organization, or the like. As illustrated in FIG. 14, the data center 600 may include a plurality of application servers (e.g., a first application server 50_1 to an n-th application server 50_n, where n is a positive integer greater than one (1)) and a plurality of storage servers (e.g., a first storage server 60_1 to an m-th storage server 60_m, where m is a positive integer greater than one (1)). The number of the application servers (e.g., n) and the number of the storage servers (e.g., m) may be variously selected, according to an embodiment, and n and m may be different from each other.

The plurality of application servers 50_1 to 50_n may include at least one of a plurality of processors (e.g., a first processor 51_1 to an n-th processor 51_n), a plurality of memories (e.g., a first memory 52_1 to an n-th memory 52_n), a plurality of switches (e.g., a first switch 53_1 to an n-th switch 53_n), a plurality of network interface controllers (NIC) (e.g., a first NIC 54_1 to an n-th NIC 54_n), and a plurality of storage devices (e.g., a first storage device 55_1 to an n-th storage device 55_n). The plurality of processors 51_1 to 51_n may control all operations of the plurality of application servers 50_1 to 50_n and may access the plurality of memories 52_1 to 52_n to perform instructions and/or data loaded in the plurality of memories 52_1 to 52_n. The plurality of memories 52_1 to 52_n may be and/or may include, but not be limited to, double data rate synchronous DRAM (DDR SDRAM), high bandwidth memory (HBM), hybrid memory cube (HMC), dual in-line memory module (DIMM), Optane DIMM, non-volatile DIMM (NVMDIMM), or the like.

In some embodiments, the number of processors and the number of memories included in the plurality of application servers 50_1 to 50_n may be variously selected. In some embodiments, the plurality of processors 51_1 to 51_n and the plurality of memories 52_1 to 52_n may provide processor-memory pairs. In some embodiments, the number of the plurality of processors 51_1 to 51_n and the number of the plurality of memories 52_1 to 52_n may be different from each other. The plurality of processors 51_1 to 51_n may include single-core processors and/or multi-core processors. In some embodiments, as marked with the dotted line in FIG. 14, the plurality of storage devices 55_1 to 55_n may be omitted from the plurality of application servers 50_1 to 50_n. The number of the plurality of storage devices 55_1 to 55_n included in the plurality of application servers 50_1 to 50_n may be variously selected, according to an embodiment. The processors plurality of 51_1 to 51_n, the plurality of memories 52_1 to 52_n, the plurality of switches 53_1 to 53_n, the plurality of NICs 54_1 to 54_n, and/or the plurality of storage devices 55_1 to 55_n may communicate with each other through a link described above in relation to the drawings.

The plurality of storage servers 60_1 to 60_m may include at least one of a plurality of processors (e.g., a first processor 61_1 to an m-th processor 61_m), a plurality of memories (e.g., a first memory 62_1 to an m-th memory 62_m), a plurality of switches (e.g., a first switch 63_1 to an m-th switch 63_m), a plurality of NICs (e.g., a first NIC 64_1 to an m-th NIC 64_m), and a plurality of storage devices (e.g., a first storage device 65_1 to an m-th storage device 65_m). The plurality of processors 61_1 to 61_m and the plurality of memories 62_1 to 62_m may operate similarly to the plurality of processors 51_1 to 51_n and the plurality of memories 52_1 to 52_n of the plurality of application servers 50_1 to 50_n described above.

The plurality of memories 52_1 to 52_n and the plurality of memories 62_1 to 62_m respectively included in the plurality of application servers 50_1 to 50_n and the plurality of storage servers 60_1 to 60_m may include a memory device (e.g., the memory device 200, the memory device 300, or the memory device 520), according to various embodiments. For example, the plurality of memories 52_1 to 52_n and the plurality of memories 62_1 to 62_m may include volatile memory devices, and when the activation operation is performed with respect to the word lines, the value of the data stored in the sense amplifier circuit 522 may be inverted, and the operation of restoring the inverted data in the memory cells may be performed.

The plurality of application servers 50_1 to 50_n and the plurality of storage servers 60_1 to 60_m may communicate with each other through a network 70. In some embodiments, the network 70 may be implemented by using Fibre Channel (FC), Ethernet, or the like. The FC may be a medium used for high-speed data transmission, and an optical switch providing high performance/availability may be used as the FC. According to an access method of the network 70, the plurality of storage servers 60_1 to 60_m may be provided as a file storage, a block storage, or an object storage.

In some embodiments, the network 70 may be a storage network such as, but not limited to, a storage area network (SAN). For example, the SAN may be an Fibre Channel SAN (FC-SAN) using an FC network and implemented according to an FC protocol (FCP). Alternatively or additionally, the SAN may be an Internet Protocol (IP) SAN (IP-SAN) using a transmission control protocol/IP (TCP/IP) network and implemented according to an internet small computer systems interface (iSCSI, SCSI over TCP/IP or Internet SCSI) protocol. In some embodiments, the network 70 may be a general network such as, but not limited to, a TCP/IP network. For example, the network 70 may be implemented according to a protocol such as, but not limited to, FC over Ethernet (FCoE), network attached storage (NAS), nonvolatile memory express (NVMe) over Fabrics (NVMe-oF), or the like.

Hereinafter, for ease of description, the first application server 50_1 and the first storage server 60_1 are described. However, the description of the first application server 50_1 may be applied to other application servers (e.g., the remaining application servers of the plurality of application servers 50_2 to 50_n), and the description of the first storage server 60_1 may be applied to other storage servers (e.g., the remaining storage servers of the plurality of storage servers 60_2 to 60_m).

The first application server 50_1 may store data requested by a user or a client in one of the plurality of storage servers 60_1 to 60_m through the network 70. In addition, the first application server 50_1 may obtain data requested by a user or a client from one of the plurality of storage servers 60_1 to 60_m through the network 70. For example, the first application server 50_1 may be implemented as a web server, a database management system (DBMS), or the like.

The first application server 50_1 may access a storage device (e.g., one of the plurality of storage devices 55_2 to 55_n) and/or a memory (e.g., one of the plurality of memories 52_2 to 52_n) included in another application server (e.g., one of the plurality of application servers 50_2 to 50_n) through the network 70, and/or may access a storage device (e.g., one of the plurality of storage devices 65_1 to 65_m) and/or a memory (e.g., one of the plurality of memories 62_1 to 62_m) included in the plurality of storage servers 60_1 to 60_m through the network 70.

Accordingly, the first application server 50_1 may perform various operations with respect to the data stored in the plurality of storage servers 60_1 to 60_m and/or the plurality of application servers 50_1 to 50_n. For example, the first application server 50_1 may carry out an instruction to copy and/or move data between the plurality of storage servers 60_1 to 60_m and/or the plurality of application servers 50_1 to 50_n. The data may directly move from the plurality of storage devices 65_1 to 65_m of the plurality of storage servers 60_1 to 60_m to the plurality of memories 52_1 to 52_n of the plurality of application servers 50_1 to 50_n directly or through the plurality of memories 62_1 to 62_m of the storage servers 60_1 to 60_m. In some embodiments, the data transmitted through the network 70 may be data encoded for security and/or privacy.

In the first storage server 60_1, an interface IF may provide a physical connection between the processor 61_1 and the controller CTRL and/or a physical connection between the first NIC 64_1 and the controller CTRL. For example, the interface IF may be implemented by a direct attached storage (DAS) method in which the first storage device 65_1 is accessed directly by using a dedicated cable. As another example, the interface IF may conform with various interface standards and/or protocols such as, but not limited to, advanced technology attachment (ATA), serial ATA (SATA), external SATA (e-SATA), small computer small interface (SCSI), serial attached SCSI (SAS), peripheral component interconnection (PCI), PCI express (PCIe), NVM express (NVMe), Institute of Electrical and Electronics Engineers (IEEE) 1394 (Firewire), universal serial bus (USB), secure digital (SD) card, multi-media card (MMC), embedded multi-media card (eMMC), universal flash storage (UFS), embedded universal flash storage (eUFS), compact flash (CF) card interface, or the like.

In the first storage server 60_1, the first switch 63_1 may selectively connect the first processor 61_1 to the first storage device 65_1 and/or selectively connect the first NIC 64_1 to the first storage device 65_1 according to control by the first processor 61_1.

In some embodiments, the first NIC 64_1 may include a network interface card, a network adapter, or the like. The first NIC 54_1 may be connected to the network 70 by a wired interface, a wireless interface, a Bluetooth™ interface, an optical interface, or the like. The first NIC 54_1 may include an internal memory, a digital signal processor (DSP), a host bus interface, or the like and may be connected to the first switch 63_1 and/or the first processor 61_1 through the host bus interface. In some embodiments, the first NIC 64_1 may be integrated with at least one of the first processor 61_1, the first switch 63_1, and the first storage device 65_1.

In the plurality of application servers 50_1 to 50_n or the plurality of storage servers 60_1 to 60_m, the plurality of processors 51_1 to 51_m and the plurality of processors 61_1 to 61_n may program and/or read data by transmitting a command to the plurality of storage devices 55_1 to 55_n, the plurality of storage devices 65_1 to 65_m, the plurality of memories 52_1 to 52_n, or the plurality of memories 62_1 to 62_m. The data may be data of which errors are corrected by an error correction code (ECC) engine. The data may be data on which data bus inversion (DBI) or data masking (DM) is performed and may include cyclic redundancy code (CRC) information. The data may be encoded for security and/or privacy.

The plurality of storage devices 55_1 to 55_n and the plurality of storage devices 65_1 to 65_m may transmit a control signal and/or a command/address signal to a non-volatile memory device (e.g., a NAND flash memory device, a NVM, or the like) in response to a read command received from the plurality of processors 51_1 to 51_m or the plurality of processors 61_1 to 61_n. Accordingly, when the data is read from the non-volatile memory device NVM, for example, a read enable signal may be input as a data output control signal and may be used to output data to a DQ bus. By using the read enable signal, a data strobe signal may be generated. The command and the address signal may be latched according to a rising edge or a falling edge of a write enable signal.

The controller CTRL may control operations of the first storage device 65_1. In an embodiment, the controller CTRL may include a static random access memory (SRAM). The controller CTRL may write data on the non-volatile memory device NVM in response to a write command and/or may read data from the non-volatile memory device NVM in response to a read command. For example, the write command and/or the read command may be generated based a request provided from a host, for example, the first processor 61_1 in the first storage server 60_1, a processor (e.g., one of the plurality of processors 61_2 to 61_m) in another storage server (e.g., one of the plurality of storage servers 60_2 to 60_m), or a processor (e.g., one of the plurality of processors 51_1 to 51_n) in an application server (e.g., one of the plurality of application servers 50_1 to 50_n).

A buffer BUF may temporarily store (buffer) data to be written on the non-volatile memory device NVM or data read from the non-volatile memory device NVM. In some embodiments, the buffer BUF may include DRAM. In addition, the buffer BUF may store metadata, and the metadata may refer to user data or data generated from the controller CTRL to manage the non-volatile memory device NVM. The first storage device 65_1 may include a secure element (SE) for security and/or privacy.

While the present disclosure has been particularly shown and described with reference to embodiments thereof, it is to be understood that various changes in form and details may be made therein without departing from the spirit and scope of the following claims.

What is claimed is:

1. A memory device, comprising:
a memory cell array comprising a plurality of word lines;
a sense amplifier circuit configured to:
amplify read data obtained from active memory cells of an active word line from among the plurality of word lines, and
provide write data from a memory controller to the active memory cells; and
a control logic circuit configured to store, based on activation of a first word line of the plurality of word lines, inverted first data in memory cells of the first word line by inverting first data of the memory cells of the first word line stored in the sense amplifier circuit.

2. The memory device of claim 1, wherein the control logic circuit comprises an inverter circuit comprising a plurality of inverters configured to invert data values stored in the sense amplifier circuit.

3. The memory device of claim 1, wherein the control logic circuit is further configured to:
store, based on reactivation of the first word line, the first data in the memory cells of the first word line by inverting the inverted first data read from the memory cells of the first word line and stored in the sense amplifier circuit,.

4. The memory device of claim 1, wherein the control logic circuit is further configured to:
store, in a write operation for a second word line from among the plurality of word lines, inverted write data in one or more first memory cells of the second word line by inverting write data provided by the memory controller.

5. The memory device of claim 4, wherein the sense amplifier circuit is further configured to store, based on the second word line being active in the write operation for the second word line, second data of the second word line,
wherein the second data comprises the write data provided by the memory controller and data stored in one or more second memory cells of the second word line, and
wherein the control logic circuit is further configured to store inverted second data in memory cells of the second word line by inverting the second data stored in the sense amplifier circuit.

6. The memory device of claim 1, further comprising:
a storage circuit configured to store polarity information indicating whether data stored in memory cells of each word line of the plurality of word lines is an inverted value of original data provided by the memory controller.

7. The memory device of claim 6, further comprising:
a first selector configured to:
receive the read data output from the sense amplifier circuit and inverted read data obtained by inverting the read data, and
selectively output at least one of the read data or the inverted read data based on the polarity information; and
an error correction code (ECC) decoder configured to perform ECC decoding on the at least one of the read data or the inverted read data output by the first selector.

8. The memory device of claim 7, further comprising:
a second selector configured to:
receive the write data provided by the memory controller and inverted write data obtained by inverting a value of the write data, and
selectively output at least one of the write data or the inverted write data based on the polarity information; and
an ECC encoder configured to perform ECC encoding on the at least one of the write data or the inverted write data output by the second selector.

9. The memory device of claim 6, wherein the memory cell array further comprises a plurality of per-row activation counting (PRAC) cells disposed in correspondence to each word line of the plurality of word lines,
wherein at least one PRAC cell of the plurality of PRAC cells stores an activation count value of a corresponding word line, and
wherein the storage circuit comprises one or more PRAC cells storing a flag comprising one or more bits as the polarity information.

10. The memory device of claim 1, wherein the control logic circuit is further configured to:
identify one or more word lines of the plurality of word lines as an aggressor word line based on the one or more word lines being more active during a time period than remaining word lines of the plurality of word lines, and
selectively invert, based on the first word line corresponding to the aggressor word line, a value of the first data stored in the sense amplifier circuit.

11. An operating method of a memory device, the operating method comprising:
activating a first word line from among a plurality of word lines of the memory device, based on reception of an active command from a memory controller;
storing, in a sense amplifier circuit, first data read from first memory cells of the first word line;
storing, based on reception of a first command from the memory controller, inverted first data in the first memory cells by inverting the first data stored in the sense amplifier circuit; and
storing, in a storage circuit of the memory device, a first flag indicating a polarity of the first data stored in the first memory cells.

12. The operating method of claim 11, further comprising:
activating the first word line based on reception of the active command from the memory controller;
storing, in the sense amplifier circuit, the inverted first data read from the first memory cells;
storing, based on reception of the first command, the first data in the first memory cells by inverting the inverted first data stored in the sense amplifier circuit; and
updating the first flag stored in the storage circuit to a second value.

13. The operating method of claim 11, wherein the first command comprises a precharge command, and
wherein the operating method further comprises:
precharging bit lines coupled with the first memory cells to a predetermined precharge level after the inverted first data is stored in the first memory cells.

14. The operating method of claim 11, further comprising:
activating a second word line from among the plurality of word lines based on reception of the active command;
receiving write data to be written to second memory cells of the second word line;
accessing a second flag corresponding to the second word line stored in the storage circuit; and
writing, based on the second flag having a first value, inverted write data to the second memory cells by inverting the write data.

15. The operating method of claim 14, further comprising:
writing, based on the second flag having a second value, the write data to the second memory cells without inverting the write data.

16. The operating method of claim 11, further comprising:
storing, in a per-row activation counting (PRAC) cell corresponding to a word line of the plurality of word lines of the memory device, an activation count of a corresponding word line.

17. The operating method of claim 16, wherein the storing of the inverted first data in the first memory cells comprises:
selectively inverting the first data stored in the sense amplifier circuit, based on the activation count corresponding to the first word line being greater than a predetermined reference value.

18. An operating method of a memory device, the operating method comprising:
activating a word line from among a plurality of word lines of the memory device based on reception of an active command from a memory controller;
storing, in memory cells of the word line based on the word line being active, inverted data obtained by inverting data of the memory cells of the word line stored in a sense amplifier circuit of the memory device;
updating, in a first per-row activation counting (PRAC) cell of the memory device corresponding to the word line, an activation count of the word line; and
updating, in a second PRAC cell of the memory device, a flag indicating a polarity of data stored in the memory cells of the word line to a predetermined value, based on the polarity of the data stored in the memory cells of the word line being inverted.

19. The operating method of claim 18, further comprising:
accessing the inverted data from the memory cells of the word line;
obtaining the flag indicating the polarity of the data stored in the memory cells of the word line; and
outputting, to a host, the data generated by inverting the inverted data based on the flag having the predetermined value.

20. The operating method of claim 18, further comprising:
receiving, from a host, write data;
accessing the flag stored in the second PRAC cell; and
writing inverted write data to the memory cells of the word line by inverting the write data based on the flag having the predetermined value.
